(19) United States
(12) Patent Application Publication
(10) Pub. No.: US 2015/0214957 A1
(43) Pub. Date: Jul. 30, 2015

(54) TEMPERATURE COMPENSATED OSCILLATOR AND CONTROL METHOD THEREOF

(71) Applicant: HARMONY ELECTRONICS CORP., Kaohsiung City (TW)

(72) Inventors: Hsin-Hung LI, TAICHUNG CITY (TW); Shui-Yuan HSIEH, KAOHSIUNG CITY (TW)

(73) Assignee: HARMONY ELECTRONICS CORP., Kaohsiung City (TW)

(21) Appl. No.: 14/219,009

(22) Filed: Mar. 19, 2014

(30) Foreign Application Priority Data
Jan. 24, 2014 (TW) 103102724

(51) Int. Cl. H03L 1/02; B81B 7/00; H03B 5/30

(52) U.S. Cl. CPC H03L 1/022; H03B 5/30; B81B 7/008

(57) ABSTRACT

A temperature compensated oscillator and a control method are provided. The oscillator includes a Micro Electro Mechanical Systems (MEMS) resonator group, a heating device, and a controller. The MEMS resonator group includes a first MEMS resonator and a second MEMS resonator. The first MEMS resonator outputs a main oscillation frequency according to a control signal. The second MEMS resonator outputs an auxiliary oscillation frequency according to a temperature of the second MEMS resonator. The heating device increases a temperature of the MEMS resonator group. The controller controls the heating device according to a difference between the main oscillation frequency and the auxiliary oscillation frequency. In the control method, at first, the MEMS resonator group is provided. Thereafter, a frequency difference between the main oscillation frequency and the auxiliary oscillation frequency is calculated. Then, the temperature of the MEMS resonator group is controlled according to the frequency difference.

### RELATED APPLICATIONS

This application claims priority to Taiwan Application Serial Number 103102724, filed on Jan. 24, 2014, which is herein incorporated by reference.

### BACKGROUND

1. Field of Invention

The present disclosure relates to a temperature compensated oscillator and a control method thereof. More particularly, the present disclosure relates to a micro electro mechanical systems (MEMS) temperature compensated oscillator and a control method thereof.

2. Description of Related Art

An oscillator is an electronic device used to generate a periodic signal (such as a square wave or a sine wave). Currently, a common electric device, such as a signal generator, a frequency synthesizer, or a phase lock loop, uses an oscillator to provide periodic signals required for operation.

A quartz oscillator is one of the most popular oscillators presently. Since the quartz oscillator has advantages of simple structure and low cost, the quartz oscillator is popularly used in various electronic products. However, due to the limitation of mechanical cutting operations and polishing operations used to process quartz crystals, it is not easy to fabricate a quartz element having a small size and a high frequency. Therefore, a trend of using a micro electro mechanical systems (MEMS) oscillator to replace the quartz oscillator is gradually developed.

For fabricating the MEMS oscillator, a MEMS technology is first used to fabricate a resonator structure, and then a System in Package (SiP) technology is used to integrate a controller and the resonator structure in a single chip package. Since the MEMS resonator is formed from silicon, the processes for fabricating the MEMS oscillator are compatible with semiconductor processes. Also, the MEMS oscillator has various oscillation modes, and thus a high frequency element with a small size can be fabricated thereby. However, since being affected by a Temperature Coefficient of Young's Modulus (TCE), a Coefficient of Thermal Expansion (CTE), etc. of the MEMS resonator, the frequency of the MEMS resonator is drifted with temperature changes. Therefore, a temperature compensation design is needed to increase the stability of the frequency of the MEMS resonator.

### SUMMARY

An aspect of the present disclosure is to provide a temperature compensated oscillator and a control method thereof. The temperature compensated oscillator and the control method thereof use a MEMS resonator to sense an environment temperature, thereby controlling a work state of a heating device to maintain temperature of MEMS resonators of the temperature compensated oscillator at a predetermined temperature.

According to an embodiment of the present disclosure, the temperature compensated oscillator includes a MEMS resonator group, a heating device, and a controller. The MEMS resonator group includes a first MEMS resonator and a second MEMS resonator. The first MEMS resonator is configured to output a first periodic signal in accordance with a control signal, wherein the first periodic signal has a main oscillation frequency. The second MEMS resonator is configured to output a second periodic signal in accordance with temperature of the second MEMS resonator, wherein the second periodic signal has an auxiliary oscillation frequency. The heating device is configured to increase temperature of the MEMS resonator group. The controller is configured to control the heating device in accordance with a difference between the main oscillation frequency and the auxiliary oscillation frequency. The controller includes a counter and a temperature control unit. The counter is configured to calculate a frequency difference between the main oscillation frequency and the auxiliary oscillation frequency. The temperature control unit is configured to control the heating device in accordance with the frequency difference.

According to another embodiment of the present disclosure, in the control method of the temperature compensated oscillator, at first, a MEMS resonator group is provided, in which the MEMS resonator group includes a first MEMS resonator and a second MEMS resonator. Then, the first MEMS resonator and the second MEMS resonator are drove to output first periodic signal and a second periodic signal, in which the first periodic signal has a main oscillation frequency, and the second periodic signal has an auxiliary oscillation frequency. Thereafter, a frequency difference between the main oscillation frequency and the auxiliary oscillation frequency is calculated. Then, a temperature control operation to control a heating device to adjust temperature of the MEMS resonator group is performed.

It can be known from the above descriptions that the temperature compensated oscillator of the present disclosure includes two resonators, in which the first MEMS resonator is used to output the main oscillation frequency desired by a user, and the second MEMS resonator is used to sense the change of temperature and to output the auxiliary oscillation frequency accordingly. By receiving the difference between the main oscillation frequency and the auxiliary oscillation frequency, the controller can turn on or turn off the heater in accordance with the temperature change of the resonators, and thus the first MEMS resonator can work at the predetermined temperature.

### BRIEF DESCRIPTION OF THE DRAWINGS

These and other features, aspects, advantages and embodiments of the present disclosure will become better understood with regard to the following accompanying drawings where:

FIG. 1 shows a functional block diagram of a temperature compensated oscillator in accordance with embodiments of the present invention;

FIG. 2 shows a top view of the temperature compensated oscillator in ordance with embodiments of the present invention;

FIG. 3 shows relationships between temperature and output frequencies of the MEMS resonator group in accordance with the embodiments of the present invention;

FIG. 4 shows a functional block of the controller of the embodiments of the present invention;

FIG. 5 shows a flow chart of a control method of the temperature compensated oscillator in accordance with embodiments of the present invention;

FIG. 6A shows a functional diagram of a temperature compensated oscillator in accordance with embodiments of the present invention; and

FIG. 6B shows relationships between temperature and output frequencies of a MEMS resonator group in accordance with the embodiments of the present invention.

### DETAILED DESCRIPTION

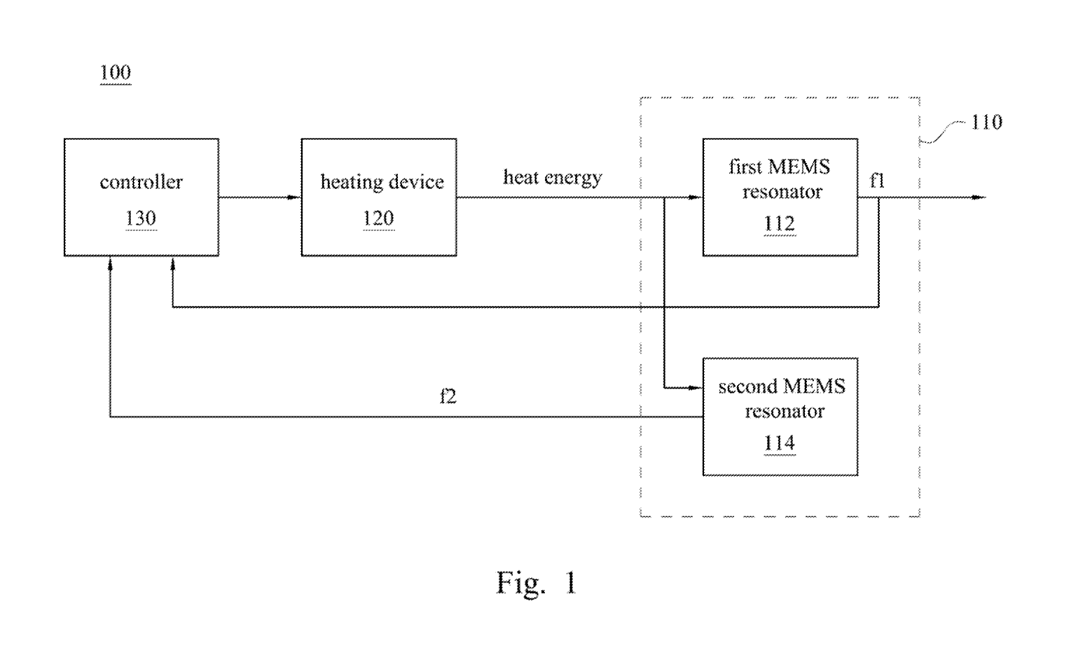

Referring to FIG. 1. FIG. 1 shows a functional block diagram of a temperature compensated oscillator 100 in accordance with embodiments of the present invention. The temperature compensated oscillator 100 includes a MEMS resonator group 110, a heating device 120, and a controller 130. In the embodiments of the present invention, the heating device 120 is configured to increase temperature of the MEMS resonator group 110, and the controller 130 is configured to control a work state of the heating device 120 in accordance with a difference of the frequencies output by the MEMS resonator group 110.

The MEMS resonator group 110 includes a first MEMS resonator 112 and a second MEMS resonator 114. The first MEMS resonator 112 is configured to output a first periodic signal having a main oscillation frequency f1. The second MEMS resonator 114 is configured to output a second periodic signal in accordance with temperature of the second MEMS resonator 114, in which the second periodic signal has an auxiliary oscillation frequency f2. In the present embodiment, the oscillator 100 is a temperature compensated MEMS oscillator, and thus the first MEMS resonator 112 and the second MEMS resonator 114 maintain the main oscillation frequency f1 and the auxiliary oscillation frequency f2 in accordance with voltage signals provided by internal driving circuits. However, the embodiments of the present invention are not limited thereto.

In general, main material of MEMS resonators is silicon, and a temperature coefficient of frequency (TCF) of silicon is negative. In order to decrease temperature sensitivity of the main oscillation frequency f1 the first MEMS resonator 112 is formed from composite material in which material having a positive TCF, such as SiO₂, is embedded. However, the embodiments of the present invention are not limited thereto.

Although the first MEMS resonator 112 of this embodiment is formed from materials including the positive TCF material, a change of temperature of the first MEMS resonator 112 may slightly affect the main oscillation frequency f1. Therefore, the heating device 120 is used to maintain the temperature of the first MEMS resonator 112 at a predetermined working temperature (for example, 85° C.), and the second MEMS resonator 114 is used to sense temperature for controlling the heating device 120 according to the sensing result, so that the temperature of the first MEMS resonator 112 can be maintained at the predetermined working temperature.

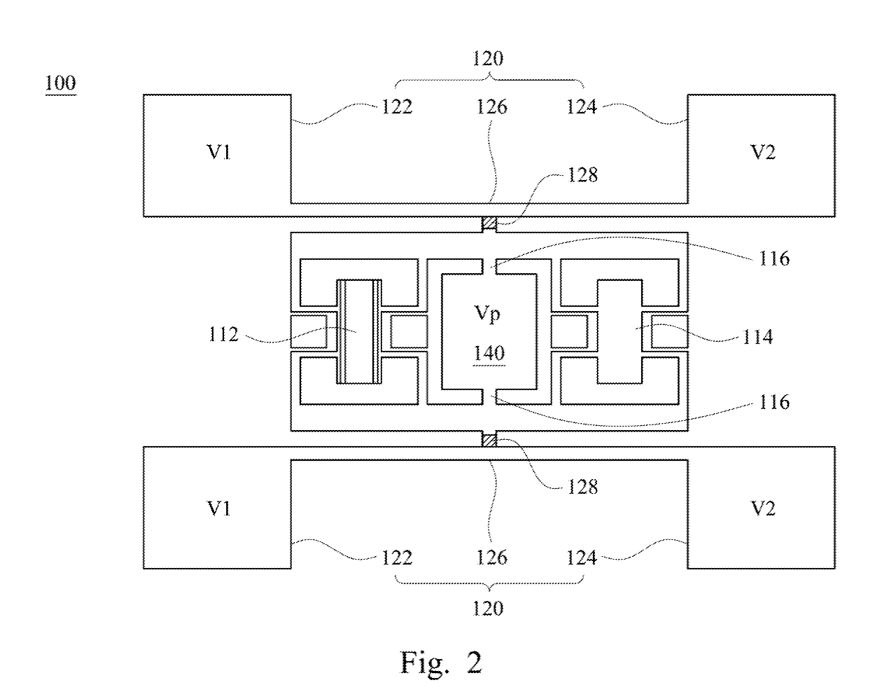

Referring to FIG. 2, FIG. 2 shows a top view of the temperature compensated oscillator 100 in accordance with embodiments of the present invention. The heater 120 includes first contact pads 122, second contact pads 124, and resistors 126. The first contact pads are used to provide a first temperature control voltage V1. The second contact pads 124 are used to provide a second temperature control voltage V2. The resistors 126 are electrically connected between the first contact pads 122 and the second contact pads 124 to use a voltage difference between the first temperature control voltage V1 and the second temperature control voltage V2 to provide heat energy to the MEMS resonator group 110.

In this embodiment, the heat energy generated by the resistors 126 may be transmitted to a frame 116 of the MEMS resonator group 110 through connection bodies 128, and then the frame 116 transmits the heat energy to the resonator group 110. The connection bodies 128 are connected between the resistors 126 and the resonator group 110 and formed from electric insulation materials. In this embodiment, the connection bodies 128 are formed from SiO₂, but embodiments of the present invention are not limited thereto. The resistors 126, the connection bodies 128, the first MEMS resonator 112, and the second MEMS resonator 114 are suspend above a semiconductor substrate (not illustrated), so that a good heat isolation environment is provided for conveniently controlling the temperature of the first MEMS resonator 112. In the package of the temperature compensated oscillator 100, air can be drew out to form an vacuum environment in the package for obtaining a better heat isolation effect.

In addition, the temperature compensated oscillator 100 further includes a proof mass voltage supply circuit 140 and gain stage circuits (not illustrated). The proof mass voltage supply circuit 140 is used to provide a proof mass voltage Vₚ to the first MEMS resonator 112 and the second MEMS resonator 114 for helping the first MEMS resonator 112 and the second MEMS resonator 114 start oscillating. The gain stage circuits include a first gain stage circuit and a second gain stage circuit. The first gain stage circuit is electrically connected to the first MEMS resonator 112 to form an oscillation circuit. The second gain stage circuit is electrically connected to the second MEMS resonator 114 to form another oscillation circuit. In the embodiments of the present invention, the first gain stage circuit and the first MEMS resonator 112 form a Pierce oscillator, and the second gain stage circuit and the second MEMS resonator 114 form another Pierce oscillator. However, the embodiments of the present invention are not limited thereto. In other embodiments of the present invention, the first gain stage circuit and the first MEMS resonator 112 may form a Copitts oscillator, and the second gain stage circuit and the second MEMS resonator 114 may form another Copitts oscillator.

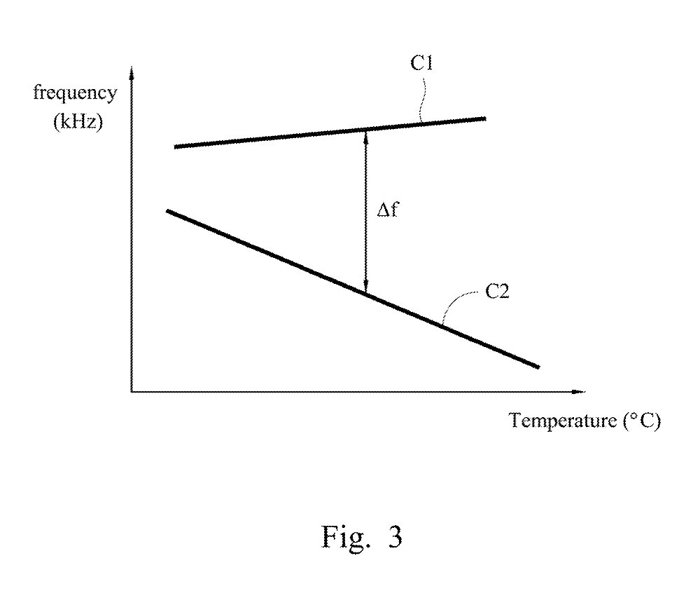

Referring to FIG. 3, FIG. 3 shows relationships between temperature and output frequencies of the MEMS resonator group 110 in accordance with the embodiments of the present invention, in which a curve C1 represents a relationship between temperature and an output frequency of the first MEMS resonator 112, and a curve C2 represents a relationship between temperature and an output frequency of the second MEMS resonator 114. As mentioned above, the first MEMS resonator 112 includes positive TCF material to decrease the temperature sensitivity of the main oscillation frequency f1. Therefore, compared with the curve C1 of the first MEMS resonator 112, the curve C2 of the second MEMS resonator 114 has a slope having a greater absolute value, so as to make the temperature sensing more convenient.

In this embodiment, the controller 130 receives the main oscillation frequency f1 output by the first MEMS resonator 112 and the auxiliary oscillation frequency 12 output by the second MEMS resonator 114, and performs a temperature control operation in accordance with a frequency difference Δf between the main oscillation frequency f1 and the auxiliary oscillation frequency f2. As shown in FIG. 3, it is represented that the temperature of the MEMS resonator group 110 is increased when the frequency difference Δf is increased. In contrast, it is represented that the temperature of the MEMS resonator group 110 is decreased when the frequency difference Δf is decreased. Therefore, in this embodiment, a frequency difference corresponding to the predetermined working temperature can be measured as a standard value of the frequency difference Δf in advance, and then the controller 130 can control the heating device 130 in accordance with the standard value of the frequency difference difference Δf.

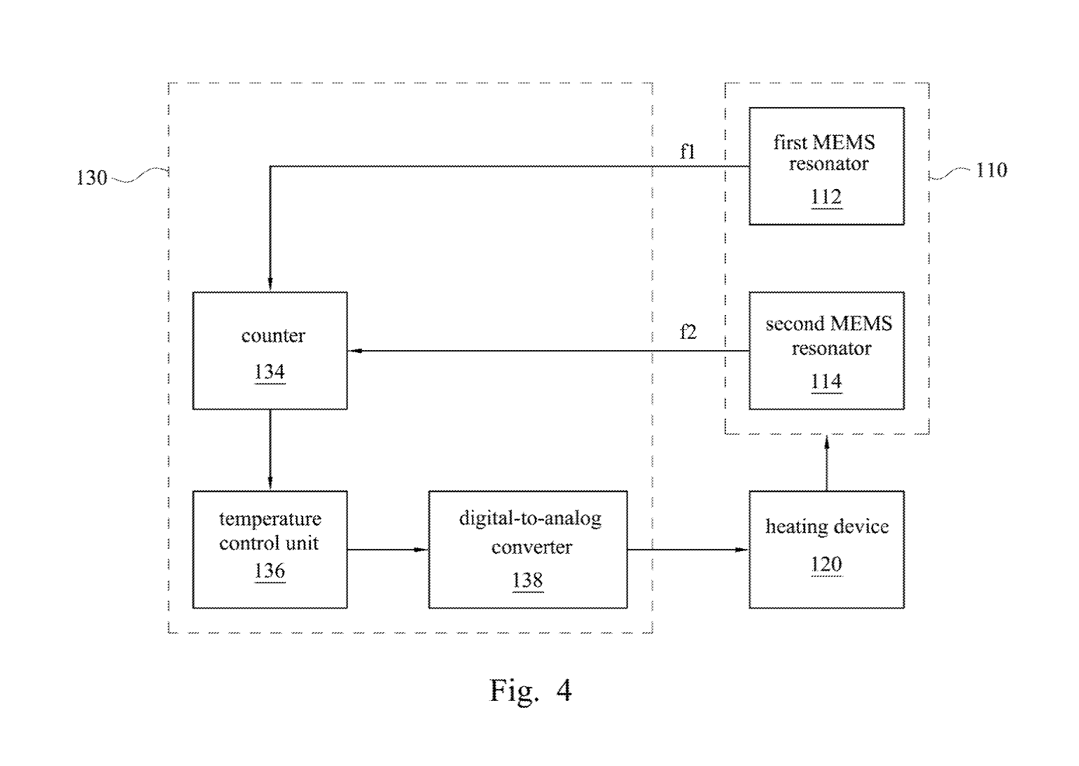

Referring to FIG. 4, FIG. 4 shows functional block of the controller 130 of the embodiments of the present invention. The controller 130 includes a counter 132, a temperature control unit 136 and a digital-to-analog converter 138.

The counter 134 is electrically connected to the first MEMS resonator 112 and the second MEMS resonator 114 to receive the first periodic signal output by the first MEMS resonator 112 and the second periodic signal output by the second MEMS resonator 114, and to calculate the frequency difference Δf between the main oscillation frequency f1 and the auxiliary oscillation frequency 12. The temperature control unit 136 is electrically connected to the counter 134 to output a first voltage control code V1_code and a second voltage control code V2_code to the digital-to-analog converter 138. The digital-to-analog converter 138 is configured to respectively convert the first voltage control code V1_code and the second voltage control code V2_code to the first temperature control voltage V1 and the second temperature control voltage V2, thereby using the heating device 120 to adjust the temperature of the MEMS resonator group 110. In addition, it is noted that the digital-to-analog converter 138 can be removed if the temperature control unit 136 can output analog signals.

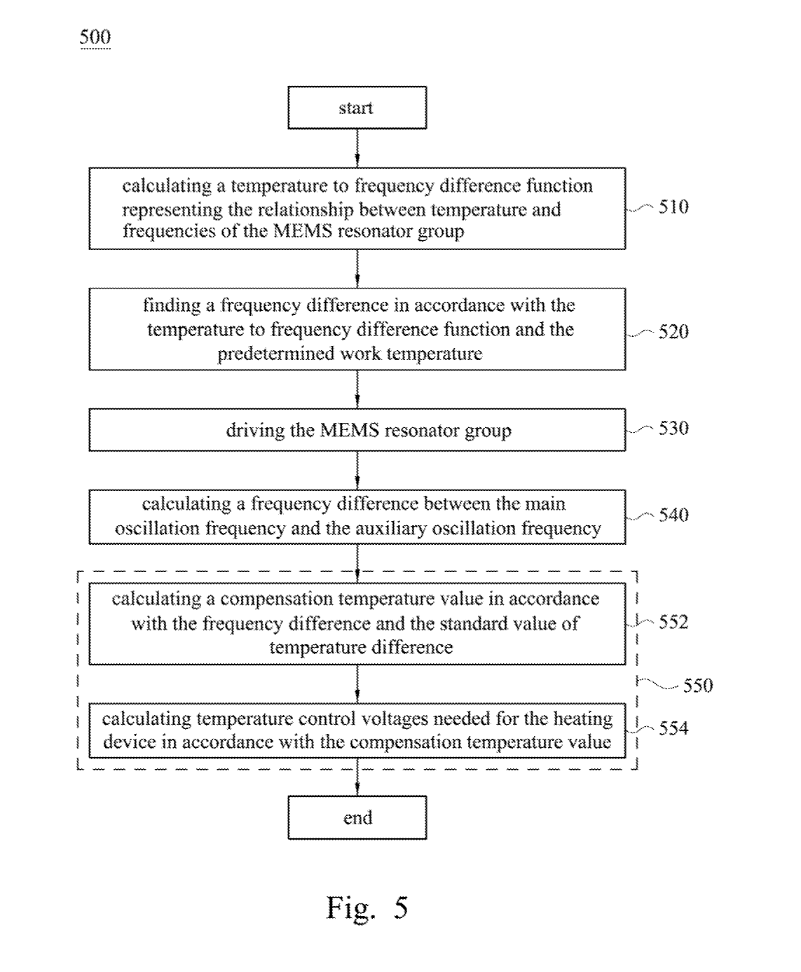

Referring to FIG. 5, FIG. 5 shows a flow chart of a control method 500 of the temperature compensated oscillator in accordance with embodiments of the present invention. In the control method 500, at first, a model establishing operation 510 is performed to calculate a temperature to frequency difference function representing the relationship between temperature and frequencies of the MEMS resonator group 110, before the temperature compensated oscillator 100 starts working. In this embodiment, since the predetermined working temperature is 85° C. three frequency differences of the MEMS resonator group 110 at 0° C., 40° C., and 85° C. are measured in the model establishing operation 510. Then, the three frequency differences are used to establish the temperature to frequency difference function in the model establishing operation 510. In this embodiment, the temperature to frequency difference function is a second-order function, but the embodiments are not limited thereto.

After the model establishing operation 510, a standard value determination operation 520 is performed to find a frequency difference corresponding to the predetermined working temperature of the temperature compensated oscillator 100 (85 in this embodiment) in accordance with the temperature to frequency difference function, and to use the frequency difference as a standard value of temperature difference. Then, a driving operation 530 is performed to drive the MEMS resonator group 110 to start working. Thereafter, a frequency difference calculating operation 540 is performed to use the counter 134 to calculate a frequency difference Δf between the main oscillation frequency f1 and the auxiliary oscillation frequency f2.

Then, a temperature control operation 550 is performed to control the heating device 120 in accordance with the frequency difference to adjust temperature of the MEMS resonator group 110. In the temperature control operation 550 of this embodiment, at first, a compensation value calculation operation 552 is performed to calculate a compensation temperature value in accordance with the frequency difference and the standard value of temperature difference. In this embodiment, a difference between the frequency difference and the standard value of frequency difference is calculated in the compensation value calculation operation 552, but the embodiments of the present invention are not limited thereto. After the compensation value calculation operation 552, a voltage calculation operation 554 is performed to calculate the first temperature control voltage V1 and the second temperature control voltage V2 needed for the heating device 120 in accordance with the compensation temperature value, and to transmit the first temperature control voltage V1 and the second temperature control voltage V2 to the heating device 120 for adjusting the temperature of the MEMS resonator group 110 to the predetermined working temperature.

It can be known from the above description that the temperature compensated oscillator 100 and the control method 500 thereof use the frequency difference between the frequencies of the first MEMS resonator 112 and the second MEMS resonator 114 to determine if the temperature of the MEMS resonator group 110 is changed, and maintain the temperature of the MEMS resonator group 110 at the predetermined working temperature in accordance with the frequency difference. Since the second MEMS resonator 114 and the first MEMS resonator 112 can be fabricated in the same process, the temperature compensated oscillator 100 of the embodiments of the present invention has advantages of simple fabrication process and low cost.

In addition, it is noted that the compensation value calculation operation 552 is performed by the temperature control unit 136, but the embodiments of the present invention are not limited thereto. In other embodiments of the present invention, the counter 134 can be used to calculate the temperature compensation value, and to provide the temperature compensation value to the temperature control unit 136 to enable the temperature control unit 136 to calculate the first temperature control voltage V1 and the second temperature control voltage V2.

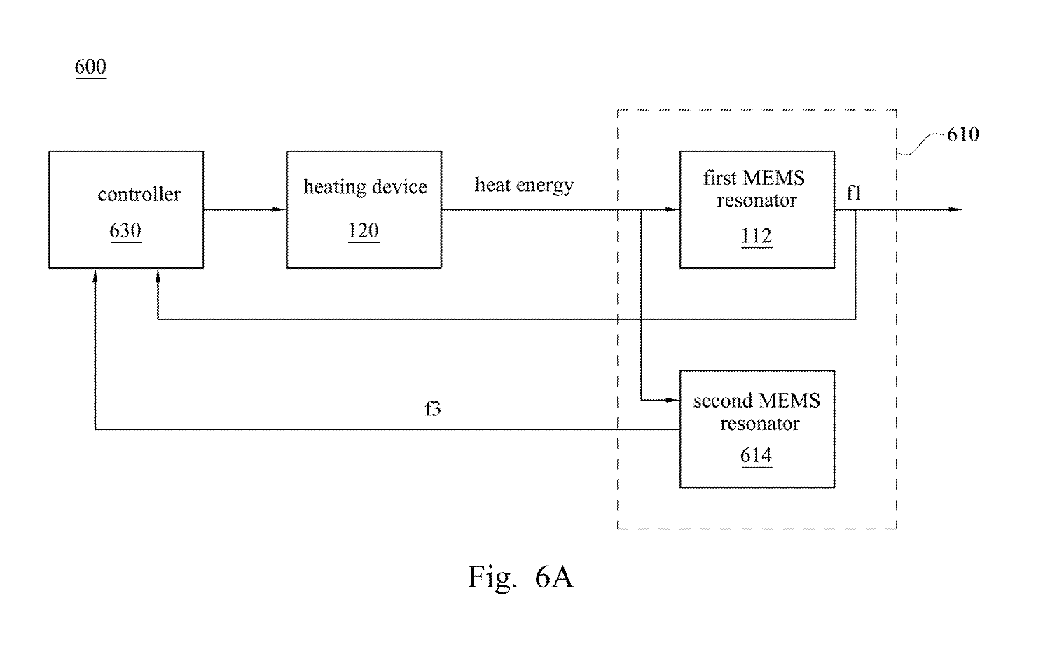

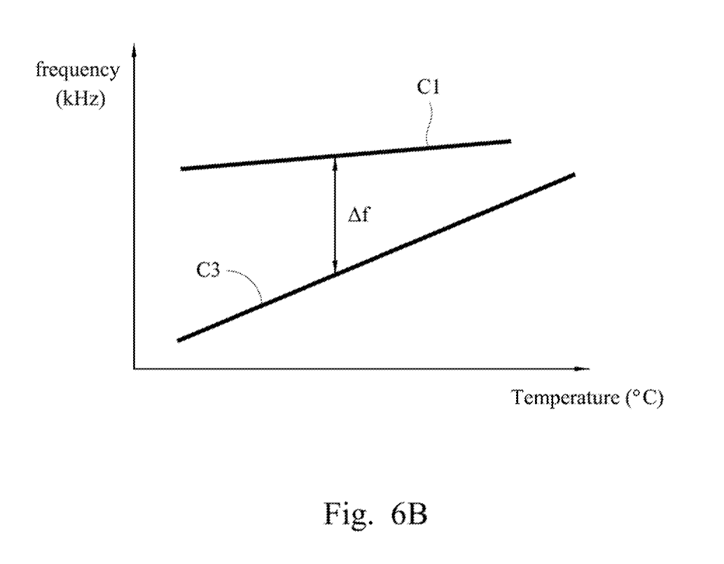

Referring to FIG. 6A and FIG. 6B simultaneously, FIG. 6A shows a functional diagram of a temperature compensated oscillator 600 in accordance with embodiments of the present invention, and FIG. 6B shows relationships between temperature and output frequencies of a MEMS resonator group 610 in accordance with the embodiments of the present invention, in which a curve C3 represents a relationship between temperature and output frequency of a second MEMS resonator 614. The temperature compensated oscillator 600 is similar to the oscillator 100, but the difference is in that the oscillator 600 includes the MEMS resonator group 610 and a controller 630.

The MEMS resonator group 610 is similar to the MEMS resonator group 110. The MEMS resonator group 610 includes the first MEMS resonator 112 and the second MEMS resonator 614. The second MEMS resonator 614 is configured to output an auxiliary oscillation frequency f3 and includes material having a positive TCF. As shown in FIG. 6B, in this embodiment, the positive TCF material enables a slope of the curve C3 be greater than that of the curve C1 of the first MEMS resonator 112. Therefore, it is represented that the temperature of the MEMS resonator group 610 is decreased when the frequency difference Δf is increased. In contrast, it is represented that the temperature of the MEMS resonator group 610 is increased when the frequency difference Δf is decreased.

The controller 630 is similar the controller 130, but the difference is in that the controller 630 controls the heating device 120 in different ways. In this embodiment, the controller 630 adjusts the temperature of the MEMS resonator group 610 by turning on or turning off the heating device 120. For example, it is represented that the temperature of the MEMS resonator group 610 is too love when the difference between the main oscillation frequency f1 and the auxiliary oscillation frequency f3 is greater than the standard value of frequency difference, and thus the controller 630 turn on the heating device 120 for increasing the temperature of the MEMS resonator group 610. For another example, it is represented that the temperature of the MEMS resonator group 610 is too high, when the difference between the main oscillation frequency f1 and the auxiliary oscillation frequency f3 is smaller than the standard value of frequency difference, and thus the controller 630 turn off the heating device 120 for decreasing the temperature of the MEMS resonator group 610.

It can be known from the above descriptions that temperature compensated oscillator 600 of the embodiments of the present invention adjusts the temperature of the MEMS resonator group 610 by turning on or turning off the heating device 120. Compared with the control method of the oscillator 100, the control method of the temperature compensated oscillator 600 is simpler. In addition, in the embodiments of the present invention, when the slope of the temperature-to-frequency curve of the first MEMS resonator is different from that of the second MEMS resonator, the temperature compensated oscillator of the embodiments of the present invention can use the frequency difference of the MEMS resonators to determine if the temperature of the MEMS resonator groups is increased or decreased, and to control the heating device accordingly.

Although the present disclosure has been described above as in some embodiments, it is not used to limit the present disclosure. It will be intended to those skilled in the art that various modifications and variations can be made to the structure of the present disclosure without departing from the scope or spirit of the disclosure. Therefore, the scope of the disclosure is to be defined solely by the appended claims.

What is claimed is:

1. A temperature compensated oscillator, comprising:
a micro electro mechanical systems (MEMS) resonator group, comprising:
a first MEMS resonator, configured to output a first periodic signal in accordance with a control signal, wherein the first periodic signal has a main oscillation frequency; and
a second MEMS resonator, configured to output a second periodic signal in accordance with temperature of the second MEMS resonator, wherein the second periodic signal has an auxiliary oscillation frequency;
a heating device, configured to increase temperature of the MEMS resonator group; and
a controller, configured to control the heating device in accordance with a difference between the main oscillation frequency and the auxiliary oscillation frequency, wherein the controller comprises:
a counter, configured to calculate a frequency difference between the main oscillation frequency and the auxiliary oscillation frequency; and
a temperature control unit, configured to control the heating device in accordance with the frequency difference.

2. The temperature compensated oscillator of claim 1, wherein a first slope of a first relationship curve representing a relationship between the main oscillation frequency and the temperature of the MEMS resonator group is not equal to a second slope of a second relationship curve representing a relationship between the auxiliary oscillation frequency and the temperature of the MEMS resonator group.

3. The temperature compensated oscillator of claim 1, comprising:
a first gain stage circuit, disposed between the first MEMS resonator and the counter to amplify the first periodic signal; and
a second gain stage circuit, disposed between the second MEMS resonator and the counter to amplify the second periodic signal.

4. The temperature compensated oscillator of claim 3, wherein the first gain stage circuit and the first MEMS resonator forms a Pierce oscillator, and the second gain stage circuit and the second MEMS resonator forms another Pierce oscillator.

5. The temperature compensated oscillator of claim 3, wherein the first gain stage circuit and the first MEMS resonator forms a Copitts oscillator, and the second gain stage circuit and the second MEMS resonator forms another Copitts oscillator.

6. The temperature compensated oscillator of claim 1, comprising a digital-to-analog converter, wherein the temperature control unit controls the heating device in accordance with a first voltage control code and a second voltage control code, and the digital-to-analog converter is configured to respectively convert the first voltage control code and the second voltage control code to a first temperature control voltage and a second temperature control voltage, and the heating device provides heat energy to the MEMS resonator group in accordance with a voltage difference between the first temperature control voltage and the second temperature control voltage.

7. The temperature compensated oscillator of claim 1, wherein the first MEMS resonator includes material having a positive temperature coefficient of frequency (TCF).

8. A method for controlling a temperature compensated oscillator, comprising:
providing a MEMS resonator group, wherein the MEMS resonator up comprises a first MEMS resonator and a second MEMS resonator;
driving the first MEMS resonator to output a first periodic signal, wherein the first periodic signal has a main oscillation frequency;
driving the second MEMS resonator to output a second periodic signal, wherein the second periodic signal has an auxiliary oscillation frequency;
calculating a frequency difference between the main oscillation frequency and the auxiliary oscillation frequency; and
performing a temperature control operation to control a heating device to adjust temperature of the MEMS resonator group.

9. The method of claim 8, wherein the heating device adjusts the temperature of the MEMS resonator group in accordance with a first voltage control code and a second voltage control code.

10. The method′ of claim 9, wherein the temperature control operator comprises:
calculating a compensation temperature value of the MEMS resonator group in accordance with the frequency difference and a standard value of frequency difference; and
calculating the first voltage control code and the second voltage control code in accordance with the compensation temperature value.
